(19) United States
(12) Patent Application Publication
(10) Pub. No.: US 2026/0229832 A1
(43) Pub. Date: Aug. 6, 2026

(54) SUBSTRATE COMPRISING SLOTS FOR HOLDING OPTICAL COMPONENTS OF A LASER CAVITY

(71) Applicant: Ecole Polytechnique Fédérale de Lausenne (EPFL), Lausanne (CH)

(72) Inventors: Antoine DELGOFFE, Morges (CH); Yves BELLOUARD, Lutry (CH); Saood Ibni NAZIR, Sunnyvale, CA (US)

(73) Assignee: Ecole Polytechnique Fédérale de Lausenne (EPFL), Lausanne (CH)

(21) Appl. No.: 19/151,034

(22) PCT Filed: Jan. 27, 2023
(86) PCT No.: PCT/IB2023/050721

§ 371 Date: Jul. 25, 2025

(51) Int. Cl. H01S 3/086; H01S 3/081

(52) U.S. Cl. CPC H01S 3/086; H01S 3/081

(57) ABSTRACT

In a substrate (1) for holding a multitude of components (6.1, 6.2, 6.3, 6.4, 6.5, 6.6) of an optical laser cavity, wherein the substrate (1) comprises a multitude of slots (2.1, 2.2, 2.3, 2.4, 2.5, 2.6), wherein each slot (2.1, 2.2, 2.3, 2.4, 2.5, 2.6) is configured to receive one of the components (6.1, 6.2, 6.3, 6.4, 6.5, 6.6), the substrate (1) comprises a micro-positioning system (4) configured to enable a micro-positioning of at least one of the components (6.1) after this component (6.1) has been received in its corresponding slot (2.1).

### TECHNICAL FIELD

The invention relates to substrate according to the preamble of claim 1. The invention furthermore relates to a method for manufacturing a substrate according to claim 13 and a method for optimizing a position of a component of an optical laser cavity on a substrate according to claim 14.

### BACKGROUND ART

An optical cavity (also referred to as resonating cavity or optical resonator) is an arrangement of optical components such as mirrors or lenses that is capable of creating standing waves in optical systems (or alternatively, circulating/traveling waves in so-called ring resonators). Optical cavities are for example typically used in laser systems. In such laser systems, light is introduced into the cavity by means of a light source which pumps a gain crystal. The photons produced by spontaneous emission are recycled by multiple passes inside the cavity and duplicated/cloned several times by the stimulated emission process, giving rise to the laser effect. This occurs only for a specific set of resonances of the optical resonator, corresponding to electromagnetic standing waves (or traveling waves) of specific frequencies. Such optical cavities typically comprise a multitude of passive optical components, such as mirrors, lenses and the like.

For optical systems (and laser systems in particular) to function properly, it is very important that the optical cavities are properly aligned in such systems. The term “alignment” basically refers to the orientations of the optical cavity's elements, one with respect to each other and/or with respect to an optical axis, for instance, as defined as the axis defining the light propagation direction (commonly indicated by the so-called k-vector). For example, a proper alignment (also referred to as “full alignment”) may be such that a path followed by a reflected light beam inside the cavity is centered through each optical element of the cavity. Already very small deviations from the proper alignment can have important negative influences on the functioning of a laser system, for example in terms of efficiency and output power. Alignment of optical cavities can be a time-consuming and complicated procedure.

In general, it is desirable to achieve the best possible alignment in optical cavities. The better the alignment is, the better the optical cavity functions, for instance, but not only, in terms of efficiency and output power and/or stability. Hence, there is a constant strive for finding ways of making the alignment of optical cavities more precise and more robust towards external disturbances, such as vibrations or temperature fluctuations.

Existing systems and methods for aligning alignment of optical cavities therefore have various disadvantages, such as being too complicated, too time-consuming, not precise enough and prone to misalignment upon external disturbances.

### Problem to be Solved

It is the object of the invention to solve or to at least diminish the above-mentioned disadvantages.

### Solution to the Problem

This problem is solved by a substrate for holding a multitude of components of an optical laser cavity, wherein the substrate comprises a multitude of slots, wherein each slot is configured to receive one of the components, wherein the substrate comprises a micro-positioning system configured to enable a micro-positioning of at least one of the components after this component has been received in its corresponding slot.

The inventors have found that a substrate comprising such a micro-positioning system solves the above-mentioned problem because it makes it possible to obtain a precise alignment of the optical laser cavity relatively easily. In addition, as it will be explained thereafter, such precise alignment can be done, at least in certain embodiments, without a direct mechanical contact, offering substantial advantages, such as the ability to work in smaller volume, in sealed-cavities through a view port, and with much higher level of accuracy as it will be shown. Throughout this description and the following claims, the word “multitude” is to be understood in the sense of “at least two”. A multitude in the sense of this application can therefore for example comprise two, three, four, five, six, more than ten or even more components.

In typical embodiments, the multitude of components is configured to form the optical laser cavity. In typical embodiments, the multitude of components is sufficient for establishing a lasing of the optical laser cavity. In typical embodiments, the at least one of the components, for the micro-positioning of which the micro-positioning system is configured, is for example an output coupler.

The expression “micro-positioning” typically refers to positioning the at least one of the components with a precision in the order of several micrometers or less and/or in the order of several milliradians or less. In typical embodiments, the micro-positioning system is configured to make a component received in its corresponding slot move by 100 micrometers or less, preferably by 0.01 micrometers to 100 micrometers, more preferably by 0.1 to 100 micrometers. In typical embodiments, the micro-positioning system is configured to rotate a component received in its corresponding slot by 100 milliradians or less, preferably by 0.1 microradians to 100 milliradians, more preferably by 1 microradian to 100 milliradians. In typical embodiments, the micro-positioning system has a translational motion range of 0 to 100 micrometers, preferably 0.1 to 90 micrometers, more preferably approximately 1 to approximately 80 micrometers. In typical embodiments, the micro-positioning system has a rotational motion range of 0 to 100 milliradians, preferably 1 microrad to 90 milliradians, more preferably approximately 1 milliradian to approximately 80 milliradians.

The micro-positioning system can also simply be called “positioning system” or “integrated positioning system”. These three terms can be used as synonyms in the present description and the following claims. Accordingly, the expression “micro-positioning” could in principle also be replaced by the word “positioning”. In general, the expression “approximately” when used in this description refers to a tolerance of +/−20 %, preferably +/−15 %, more preferably +/−10 %.

In typical embodiments, the substrate is configured such that the micro-positioning system can be actuated without establishing a direct physical contact with it. In typical embodiments, the micro-positioning system is configured to be actuated remotely.

In a typical embodiment, the micro-positioning system is configured such that a volume change induced in an actuator beam that causes a net displacement is amplified or conversely de-amplified, for example, by means of a lever amplification mechanism. In typical embodiments, the volume change comprises an expansion of material and/or a shrinkage of material.

In typical embodiments, the micro-positioning system is configured to be actuated through localized changes of volume at selected locations of the micro-positioning system. The localized changes of volume can be the result of the exposure to a laser beam, to an electrostatic force, to a local thermal source, or a magnetic field, or any mechanical means that can cause a localized densification or an expansion in given direction exploiting the Poisson coefficient of the material.

In typical embodiments, the micro-positioning system is configured to be actuated through localized changes of volume at selected locations of the micro-positioning system using an assembly of voxels defining connected or disconnected zones where non-linear absorption resulting from the exposure to an ultrafast laser has caused a structural change of the matter, itself causing a change of volume.

The expression “substrate” refers to a monolithic structure, i.e., a structure made from one single piece of material. All elements, parts and the like that are comprised in the structure are therefore typically also part of this monolithic structure, unless this is impossible for certain reasons. For example, the micro-positioning system, typically including all of its components, is typically built-in in the substrate. In other words: the entire micro-positioning system is typically integrated in the substrate, wherein the integration is typically done by a machining of the substrate as a single piece. In typical embodiments, the substrate comprises one single piece of material and all components of the substrate are formed into this single piece of material.

In typical embodiments, the micro-positioning system is configured to be actuated by means of a laser and/or by means of an electrostatic force and/or by means of a mechanical force. In typical embodiments, the micro-positioning system is configured to be displaced into an actuated position when it is actuated and to remain in this actuated position even after the actuation has stopped. The expression “actuated” is typically to be understood as “being exposed to a certain amount of energy” wherein this energy is typically provided by the laser and/or by the electrostatic force and/or by the mechanical force and/or by any combination of these. In typical embodiments, the actuation of the micro-positioning system results in a permanent strain field applied to the micro-positioning system and/or to the component that is to be micro-positioned.

In typical embodiments, an actuation by means of a laser comprises a laser writing on the micro-positioning system, in particular onto a lever of the micro-positioning system, wherein a length of the laser writing determines the micro-positioning of the component received in its corresponding slot, wherein the volume exposed to the laser typically shrinks or expands by approximately 0.03% (the value depends on the materials and laser exposition parameters).

In typical embodiments, the micro-positioning system comprises at least one micro-positioner, preferably at least two micro-positioners, more preferably three or four or five or six or seven or eight or more micro-positioners, wherein at least one micro-positioner, preferably a multitude of the micro-positioners or all micro-positioners, comprise(s) one or more deformable elements. The at least one micro-positioner (or micro-positioners, in case there is a multitude of them) can also simply be called “positioner” or “integrated positioner” (“positioners” or “integrated positioners” in case there is a multitude of them). These three terms can be used as synonyms in the present description and the following claims. Equally speaking, the at least one micro-positioner (or micro-positioners, in case there is a multitude of them) can be called ‘nano-positioner’ if its typical amplitude of motion remains less to a micrometer or if it is to refer to the resolution of the positioning than can be nanometer or sub-nanometer.

In typical embodiments, the deformable elements comprise flexure elements or are flexure elements. In typical embodiments, at least one deformable element is a flexure element. In typical embodiments, several deformable elements are flexure elements. In typical embodiments, the micro-positioners or at least some of the micro-positioners comprise(s) actuable flexure elements and/or non-actuable flexure elements. In typical embodiments, the substrate comprises a multitude of micro-positioning systems, typically one micro-positioning system per slot, wherein each micro-positioning system comprises a multitude of micro-positioners, like the ones described before.

In typical embodiments, the micro-positioning system is configured to permanently change its shape when being actuated by means of a laser, wherein preferably at least one of the micro-positioners and/or at least one of the deformable elements is/are configured to undergo a permanent shape modification when being actuated by means of the laser. In typical embodiments, at least one of the flexure elements is configured to undergo a permanent shape modification when being actuated by means of the laser. In typical embodiments, a multitude of the micro-positioners or all micro-positioners are configured to permanently change their shape when being actuated by means of a laser. In typical embodiments, at least one of the micro-positioners comprises a first region and a second region. Therein, the first region is preferably a deformable element configured to expand or shrink when being exposed to laser light, in particular to light of a femtosecond laser. Therein, the second region is preferably an elastic element which is preferably attached to the first region.

In typical embodiments, at least one of the flexure elements comprises a first region and a second region, wherein the first region is configured to permanently deform, in particular shrink or expand, when being exposed to energy, in particular laser light, and wherein the second region is configured deform elastically and is connected to the first region. In typical embodiments, the actuation by means of a laser comprises exposing a part of at least one deformable element and/or of a flexure element to laser light so as to permanently deform that part.

In typical embodiments, the micro-positioning system is configured to temporarily and/or dynamically change its shape when being actuated by means of an electrostatic force and/or by means of a mechanical force and/or by means of a force caused by thermal expansion/shrinkage of an element, wherein preferably at least one of the micro-positioners and/or at least one of the deformable elements is/are configured to undergo a temporary and/or dynamic shape modification when being actuated by means of the electrostatic force and/or by means of the mechanical force and/or by means of the force caused by thermal expansion/shrinkage of an element.

In typical embodiments, the micro-positioning system is configured to change its shape when part of its structure is subjected to a plastic deformation. The plastic deformation that causes the micro-positioning to reconfigure itself can be the results of a force applied by means of an electrostatic force and/or by means of a mechanical force and/or by means of structural changes induced in the material as a result of laser exposure. In typical embodiments, the substrate comprises an actuator, for example a piezo-electric motor, for applying the mechanic force. In typical embodiments, the substrate comprises a means for applying the electrostatic force, for instance electrodes deposited on the substrate.

In typical embodiments, the micro-positioning system is configured such that the permanent shape modification comprises a shrinkage or an expansion of material volume, in particular of substrate material volume. In typical embodiments, the permanent shape modification does not comprise an ablation. In typical embodiments, the permanent shape modification comprises a residual densification and/or a residual expansion of the substrate.

In typical embodiments, the micro-positioner is designed using one or more topology optimization method(s). In typical embodiments, a computer-generated shape is created during the one or more topology optimization method(s). In typical embodiments, the computer-generated shape comprises preferred zones. In typical embodiments, the preferred zones are used as micro-positioners and/or as actuators. In typical embodiments, the preferred zones form at least one, preferably a multitude, more preferably all of the micro-positioners and/or of the actuators.

In typical embodiments, at least one of the micro-positioners and/or deformable elements has one or two or three or more degree(s) of freedom, wherein the at least one of the micro-positioners and/or deformable elements is typically configured such that its degrees of freedom can be individually adjusted. In typical embodiments, a multitude of the micro-positioners, preferably all of the micro-positioners, have one or two or three or more degree(s) of freedom and are typically configured such that their degrees of freedom can individually adjusted. In preferable embodiments, the micro-positioning system comprises a yaw-micro-positioner and/or a pitch-micro-positioner.

In typical embodiments, the yaw-micro-positioner and the pitch-micro-positioner are arranged in series. In typical embodiments, the yaw-micro-positioner and the pitch-micro-positioner are not arranged in parallel. In typical embodiments, the yaw-micro-positioner and the pitch-micro-positioner are arranged in parallel. In typical embodiments, the yaw-micro-positioner comprises the pitch-micro-positioner. In typical embodiments, the pitch-micro-positioner is arranged in and/or nested in the yaw-micro-positioner.

In typical embodiments, the yaw-micro-positioner comprises a carrier platform, wherein the carrier platform comprises a platform slot for receiving a component on which the micro-positioning is to be performed, wherein the carrier platform preferably has an essentially rectangular surface.

In typical embodiments, the yaw-micro-positioner comprises a multitude of flexure arms, preferably four flexure arms, wherein the flexure arms connect the carrier platform to a main body of the substrate.

In typical embodiments, the yaw-micro-positioner comprises a yaw actuation flexure beam, wherein the yaw actuation flexure beam comprises a first yaw area and a second yaw area, wherein the yaw actuation flexure beam comprises a first end and a second end.

In typical embodiments, the yaw actuation flexure beam is preferably configured to shrink and/or to expand when a laser pattern is written onto the first yaw area and/or onto the second yaw area.

In typical embodiments, the first end of the yaw actuation flexure beam is attached to the main body of the substrate and wherein the second end of the yaw actuation flexure beam is attached to the carrier platform, preferably to an edge of the carrier platform.

In typical embodiments, each flexure arm is preferably attached to a corner of the carrier platform.

In typical embodiments, the yaw-micro-positioner is configured such that the carrier platform rotates around a yaw axis in a first yaw direction when a laser pattern is written on the first yaw area of the yaw actuation flexure beam and that the carrier platform rotates around the yaw axis in a second yaw direction when a laser pattern is written on a second yaw area of the yaw actuation flexure beam, wherein the first yaw direction and the second yaw direction are typically oriented in opposite directions, for example clockwise and anticlockwise.

In typical embodiments, the pitch-micro-positioner comprises a pitch actuation flexure beam, wherein the pitch actuation flexure beam comprises a first pitch area and a second pitch area.

In typical embodiments, the pitch actuation flexure beam is preferably configured to shrink and/or to expand when a laser pattern is written onto the first pitch area and/or onto the second pitch area.

In typical embodiments, the pitch actuation flexure beam preferably has an essentially rectangular form.

In preferable embodiments, the pitch-micro-positioner is configured such that the component to be micro-positioned rotates around a pitch axis in a first pitch direction when a laser pattern is written on the first pitch area of the pitch actuation flexure beam and that the component to be micro-positioned rotates around the pitch axis in a second pitch direction when a laser pattern is written on the second pitch area of the pitch actuation flexure beam, wherein the first pitch direction and the second pitch direction are typically oriented in opposite directions, for example clockwise and anticlockwise. In an embodiment where the pitch-micro-positioner is integrated in the carrier platform, it is the carrier platform that rotates around the pitch axis in a first pitch direction or in a second pitch direction, respectively.

In typical embodiments, the carrier platform comprises the pitch-micro-positioner, wherein the carrier platform comprises a yaw-sub-platform and a pitch-sub-platform, wherein the yaw-sub-platform comprises the platform slot and wherein the pitch-sub-platform comprises the pitch-micro-positioner and/or the pitch actuation flexure beam, and/or wherein the carrier platform preferably comprises a flexible transmission beam and/or wherein the carrier platform preferable comprises a rigid connection beam and/or wherein the flexible transmission beam is directly connected to the pitch-sub-platform and to the rigid connection beam and/or wherein the rigid connection beam is directly connected to the flexible transmission beam and to the yaw-sub-platform.

Throughout this specification and the following claims, the expression “flexible” typically refers to an element which can be deformed elastically (i.e. reversibly) over an intended range of motion. “Deformable”, typically refers to an element which can be deformed plastically (i.e. irreversibly) to keep a modified shape. “Rigid” typically refers to an element which cannot be deformed, at least not without destroying the element.

In typical embodiments, the yaw-sub-platform comprises a cross-pivot for supporting the yaw-sub-platform.

In typical embodiments, the yaw actuation flexure beam comprises a flexible element and a rigid element for attaching the yaw actuation flexure beam to the carrier platform. In particular embodiments, the flexible element is directly attached to the first yaw area and/or to the second yaw area. In typical embodiments, the flexible element is directly connected to the rigid element. In typical embodiments, the rigid element is directly connected to the flexible element and to the carrier platform.

In typical embodiments, a multitude of micro-positioners and/or deformable elements are distributed across the substrate and/or along a beam path of the optical laser cavity such that the micro-positioning system is preferably configured to enable micro-positioning of a multitude of the components of the laser cavity once these components have been placed in the corresponding slots. In such an embodiment with a multitude of micro-positioners and/or deformable elements, these micro-positioners and/or deformable elements are typically configured according to one or more of the above-mentioned embodiments.

In typical embodiments, the substrate comprises an embedded element, preferably a multitude of embedded elements, wherein the embedded element typically is or at least comprises a waveguide, wherein the substrate preferably comprises a multitude of waveguides.

In typical embodiments, the substrate comprises a fused silica and/or low-expansion glass and/or a ceramic, for example ULE or Zerodur, and/or a silicon. In typical embodiments the substrate is made from one of these materials or of a combination of any of them.

A method for manufacturing a substrate according to any of the above-mentioned embodiments typically comprises a step of femtosecond laser-machining and/or a step of chemical etching and/or a step of reactive-ion etching (RIE), preferably deep reactive-ion etching (DRIE). In typical embodiments, the method comprises a step of creating a computer-generated shape, wherein the step of creating a computer-generated shape preferably comprises one or more topology optimization method(s). In typical embodiments, the computer-generated shape comprises preferred zones. In typical embodiments, the preferred zones are used as micro-positioners and/or as actuators. In typical embodiments, the preferred zones form at least one, preferably a multitude, more preferably at least all of the micro-positioners and/or of the actuators. In typical embodiments, the method comprises manufacturing the entire substrate including the micro-positioning system from one single piece of material. In typical embodiments, the method comprises machining the single piece of material such that the substrate including the micro-positioning system is obtained.

The problem is furthermore solved by a method for optimizing a position of a component of an optical laser cavity on a substrate, wherein the substrate is preferably a substrate according to any of the above-mentioned embodiments, wherein the method comprises a placement step, during which the component is placed in a slot of the substrate configured to receive the component, and a micro-positioning step, during which a position of the component received in the slot is optimized by actuating a micro-positioning system of the substrate.

In typical embodiments, during the micro-positioning step, the substrate, preferably the micro-positioning system, typically a micro-positioner and/or a deformable element of the micro-positioning system, is exposed to a laser, typically a femtosecond laser and/or picosecond laser, so as to generate a preferably localized shrinkage or expansion of material volume, in particular of substrate material volume. The inventors have found that such a localized shrinkage or expansion of material volume created by laser light is a convenient way to obtain a micro-positioning of a component in a slot of a substrate for an optical laser cavity and makes it possible to obtain a very precise alignment of the optical cavity in a comparably straight-forward manner.

In typical embodiments, the exposure to a laser typically induces a permanent change of position of the component. In typical embodiments, during the micro-positioning step, the substrate, preferably the micro-positioning system, typically a micro-positioner and/or a deformable element of the micro-positioning system, is being exposed to a continuous or pulsed laser so that a localized thermal heating hot enough to induce residual densification or expansion of the substrate occurs.

### FIGURES

In the following, the invention is described in detail by means of drawings, wherein show:

FIG. 1: a schematic top view of a substrate according to the invention in a first embodiment,

FIG. 2: a schematic perspective view of the substrate of FIG. 1, with components of a laser cavity,

FIG. 3: a magnified cutout from the view of FIG. 1,

FIG. 4: a magnified cutout from the view of FIG. 3,

FIG. 5: a magnified cutout from the view of FIG. 2, as top view,

FIG. 6: a perspective cross-sectional view of a cutout from a substrate according to one embodiment of the invention,

FIG. 7: a magnified cutout from the view of FIG. 6, as side view, and

FIG. 8: a schematic view of a method for optimizing a position of a component of an optical laser cavity on a substrate, as flow diagram.

### DESCRIPTION OF PREFERRED EMBODIMENTS

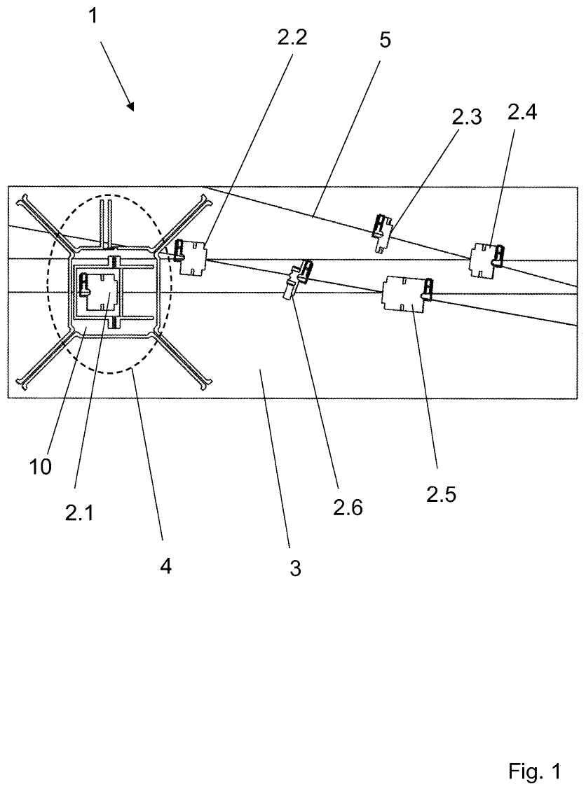

FIG. 1 shows a schematic top view of a substrate 1 according to the invention in a first embodiment. In particular, FIG. 1 shows a substrate 1 comprising a multitude of slots 2.1, 2.2., 2.3, 2.4, 2.5, 2.6. The substrate 1 comprises a main body 3 and a micro-positioning system 4. In FIG. 1, a dashed oval is used for graphically emphasising the micro-positioning system 4, wherein, however, not all parts of the micro-positioning system 4 are located inside the dashed oval. In other words: the dashed oval is for better understanding only. Five of the six slots, namely the slots 2.2, 2.3, 2.4, 2.5, 2.6 are located on the main body 3. One of the slots, namely the slot 2.1, is not located on the main body 3 but is located on a carrier platform 10. The micro-positioning system 4 comprises the carrier platform 10. Furthermore shown in FIG. 1 is a beam path 5. This beam path 5 is the beam path of a laser cavity created by various components that can be received in the slots 2.1, 2.2, 2.3, 2.4, 2.5, 2.6, when these components (not yet shown in FIG. 1) are aligned. In other words, these components, when being sufficiently aligned on the substrate 1, form a laser cavity with the beam path 5. In order to achieve a particularly precise alignment of this laser cavity, the micro-positioning system 4 can be used for micro-positioning (or in other words: adjusting) a component of the laser cavity that is received in the slot 2.1.

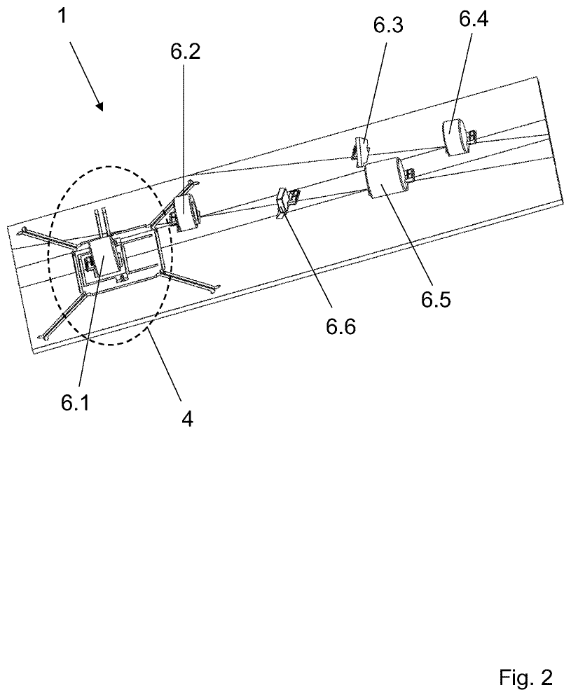

FIG. 2 shows a schematic perspective view of the substrate 1 already shown in FIG. 1 with components 6.1, 6.2, 6.3, 6.4, 6.5, 6.6 received in their respective slots on substrate 1 (the slots themselves are not equipped with reference signs in FIG. 2 for the sake of clearness). It can be seen that it is the component 6.1 that is received in its corresponding slot on the micro-positioning system 4.

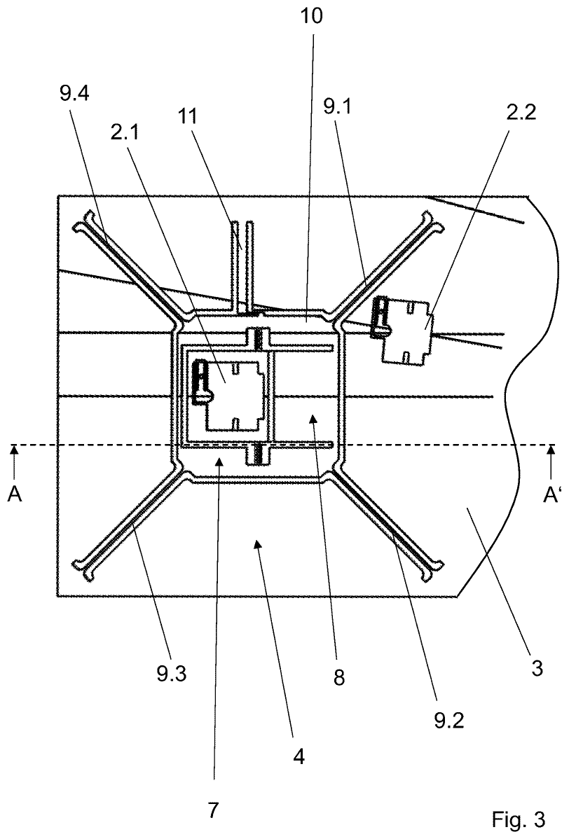

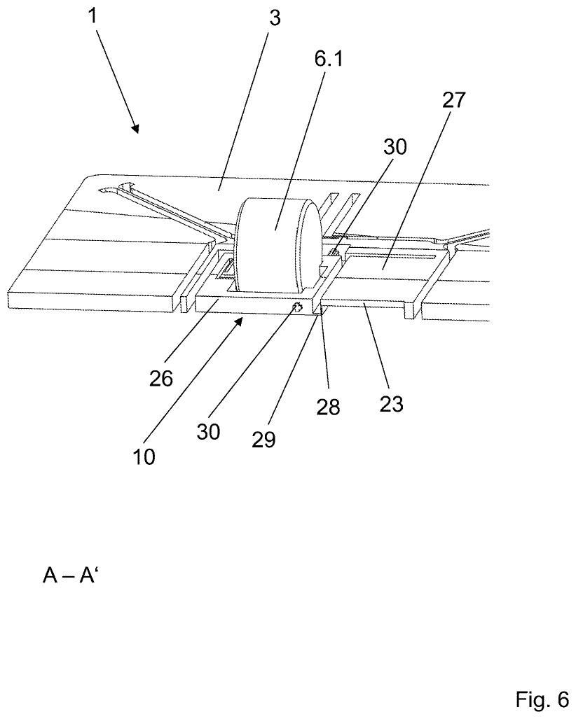

FIG. 3 shows a magnified cutout from the view of FIG. 1. In particular, FIG. 3 shows a part of the main body 3. However, not all slots that were shown in the previous Figures are shown in FIG. 3. FIG. 3 rather only shows the slot 2.2, which is located on the main body 3, and the slot 2.1 which is located on the carrier platform 10. The carrier platform 10 is connected to the main body 3 by means of four flexure arms 9.1, 9.2, 9.3, 9.4. The carrier platform 10 is furthermore connected to the main body 3 by means of a yaw actuation flexure beam 11. As can be seen in FIG. 3, each flexure arm 9.1, 9.2, 9.3, 9.4 is attached to one of the four corners of the essentially rectangular carrier platform 10. The yaw actuation flexure beam 11 is attached to one of the edges of the essentially rectangular carrier platform 10. It can be understood from FIG. 3, that the micro-positioning system 4 of the embodiment of FIG. 3 comprises the carrier platform 10, the flexure arms 9.1, 9.2, 9.3, 9.4 and the yaw actuation flexure beam 11. The micro-positioning system 4 comprises a yaw-micro-positioner 7 and a pitch micro-positioner 8. The carrier platform 10 comprises the entire pitch-micro-positioner 8. The carrier platform 10 furthermore partly comprises the yaw-micro-positioner 7. However, the yaw actuation flexure beam 11, which forms part of the yaw-micro-positioner 7 of the micro-positioning system 4 is not comprised in the carrier platform 10 but rather links the carrier platform 10 to the main body 3 as previously explained. More details of the micro-positioning system 4 will be explained in the following Figures. FIG. 3 also shows a cut line A-A′ running through parts of the main body 3 and the carrier platform 10. A sectional view according to A-A′ will be shown in FIG. 6.

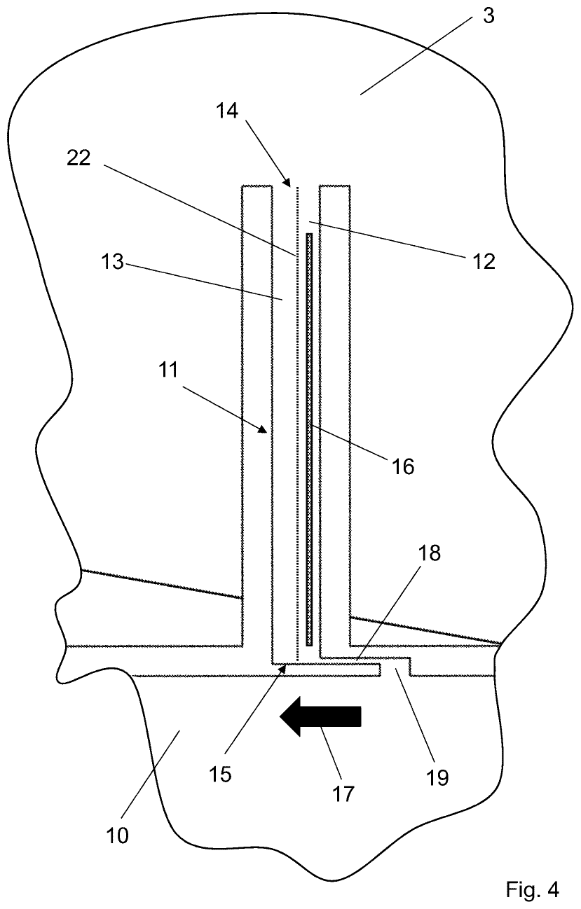

FIG. 4 shows a magnified cutout from the view of FIG. 3. In particular, FIG. 4 shows a part of the carrier platform 10, a part of the main body 3 as well as the yaw actuation flexure beam 11, which links the main body 3 to the carrier platform 10. The yaw actuation flexure beam 11 comprises a first yaw area 12 and a second yaw area 13. These two yaw areas 12, 13 are separated by a neutral area 22. A first end 14 and a second end 15 of the yaw actuation flexure beam 11 are also indicated in FIG. 4. The yaw actuation flexure beam 11 is a deformable element. When the first yaw area 12 or the second yaw area 13 of the yaw actuation flexure beam 11 is being exposed to laser light, the yaw actuation flexure beam 11 undergoes a permanent shape modification. The yaw actuation flexure beam 11, in particular its second end 15, is attached to a flexible element 18. The flexible element 18 is attached to a rigid element 19 which is attached to the carrier platform 10. In other words, the second end 15 of the yaw actuation flexure beam 11 is attached to the carrier platform 10 via the combination of the flexible element 18 and the rigid element 19. In the embodiment shown in FIG. 4, a laser pattern 16 has been written by means of a laser onto the first yaw area 12. This has led to a permanent shape modification of the yaw actuation flexure beam 11. This shape modification has been forwarded to the carrier platform 10 via the flexible element 18 and the rigid element 19. Like this, the permanent shape modification of the yaw actuation flexure beam 11 created by the laser pattern 16 has created a pulling force 17 in the carrier platform 10, indicated by an arrow pointing to the left. The influence of this pulling force 17 on the component of the laser cavity received in the slot 2.1 (not shown in FIG. 4) of the micro-positioning system will be explained in the following Figure.

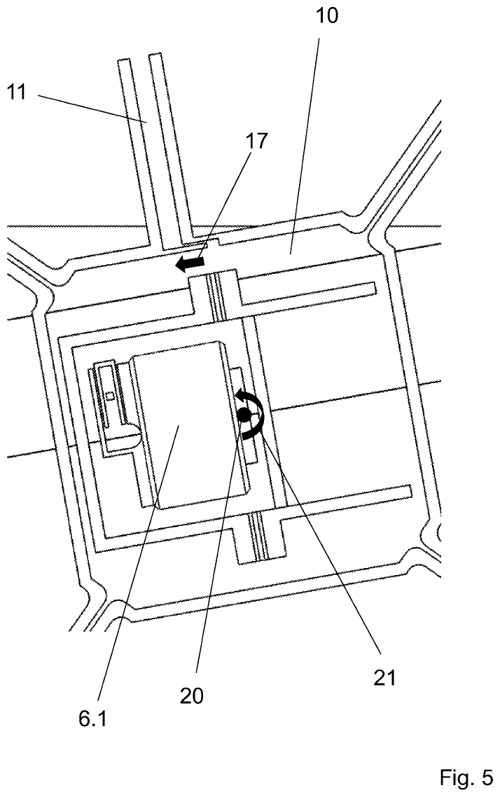

FIG. 5 shows a magnified cutout from the view of FIG. 2, as top view. In particular, FIG. 5 shows the carrier platform 10, the yaw actuation flexure beam 11 and the pulling force 17, that were already shown in FIG. 4. FIG. 5 now also shows the component 6.1, in particular a mirror of a laser cavity installed on the substrate shown for example in FIG. 2, which is received in its corresponding slot on the carrier platform 10. FIG. 5 also shows a yaw axis 20 which is directed perpendicular to the drawing plane of FIG. 5 (or in other words: which is sticking out of FIG. 5). The pulling force 17 creates an anticlockwise rotation 21 of the component 6.1 around the yaw axis 20. This rotation is typically a rotation in the range of several milliradians and is referred to as a micro-positioning of component 6.1.

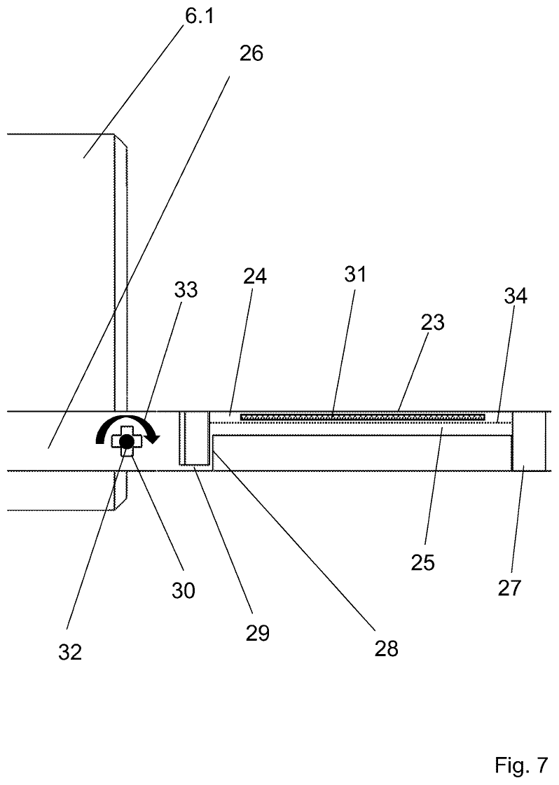

FIG. 6 now shows a perspective cross-sectional view of a cutout from a substrate according to one embodiment of the invention. In particular, FIG. 6 shows a part of a substrate 1, comprising a main body 3 and a carrier platform 10. The cross-sectional view in FIG. 6 corresponds to the cut line A-A′ indicated in FIG. 3. Received in its corresponding slot on the carrier platform 10 is the component 6.1 which is an essentially cylindrical mirror of a laser cavity installed on substrate 1. As can be seen in FIG. 6, the carrier platform 10 comprises a yaw-sub-platform 26 and a pitch-sub-platform 27. The pitch-sub-platform 27 is linked to the yaw-sub-platform 26 via a flexible transmission beam 28 and a rigid transmission beam 29. The yaw-sub-platform 26 comprises a platform slot (not equipped with reference sign in FIG. 6 for the sake of clearness), and received in this platform slot is the component 6.1. The carrier platform 10 furthermore comprises a cross pivot 30. This cross pivot 30 is configured to guide a pitch rotation of the component 6.1. As can be seen in FIG. 6, the cross pivot 30 points out of the yaw-sub-platform 26 on two opposite sides. The pitch-sub-platform 27 comprises a pitch actuation flexure beam 23 by which a pitch rotation of the component 6.1 around an imaginary axis running through the cross pivot 30 can be obtained. The actuation of the pitch actuation flexure beam 23 and thereby the obtaining of the pitch rotation of the component 6.1 will be explained in FIG. 7.

FIG. 7 now shows a magnified cutout from the view of FIG. 6, as side view. In particular, the component 6.1, which is to be micro-positioned, is once more shown in FIG. 7. The component 6.1 is placed on the yaw-sub-platform 26. The yaw-sub-platform 26 also comprises the cross pivot 30. Along the cross pivot 30 runs the pitch axis 32. FIG. 7 also shows the pitch actuation flexure beam 23 in much detail. As already mentioned, the pitch actuation flexure beam 23 is comprised in the pitch-sub-platform 27. The pitch actuation flexure beam 23 comprises a first pitch area 24 and a second pitch area 25. The first pitch area 24 and the second pitch area 25 are separated from each other by means of the neutral area 34. The pitch actuation flexure beam 23 is a deformable element. In particular, when the first pitch area 24 or the second pitch area 25 is exposed to a light of a laser, the pitch actuation flexure beam 23 permanently changes its shape. In the embodiment in FIG. 7, a laser pattern 31 has been written on the first pitch area 24. Like this, a shape modification of the pitch actuation flexure beam 23 has been obtained. The pitch actuation flexure beam 23 is linked to the yaw-sub-platform 26 via the flexible transmission beam 28 and the rigid transmission beam 29. Via this connection, the permanent shape modification of the pitch actuation flexure beam 23 induced by the laser pattern 31 creates a clockwise rotation 33 of the component 6.1 around the pitch axis 32.

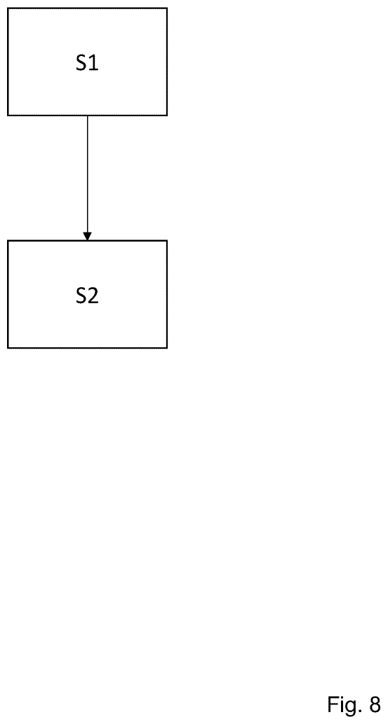

FIG. 8 shows a schematic view of a method for optimizing a position of a component of an optical laser cavity on a substrate, as flow diagram. In particular, FIG. 8 shows a placement step S1 and a micro-positioning step S2. During the placement step S1, a component of an optical laser cavity, for example a mirror, is placed in a slot configured to receive the component, wherein the slot is part of a substrate, preferably a substrate according to any one of the embodiments described above. The placement step S1 is followed by the micro-positioning step S2. During this micro-positioning step S2, a position of the component received in the slot is optimized by actuating a micro-positioning system of the substrate. The micro-positioning system is actuated by exposing a deformable element of the micro-positioning system to the light of a laser, typically a femtosecond laser and/or a picosecond laser. This exposure to laser light generates a localized shrinkage of material in the deformable element of the micro-positioning system. The shrinkage causes a force within the micro-positioning system and this force causes a movement of the component in the range of micrometers, wherein this movement can also be referred to as the micro-positioning of the component. Like this, the component received in the slot can be fine-aligned in order to optimize the alignment of the entire optical laser cavity of which the component forms part.

The invention is not limited to the preferred embodiments described here. The scope of protection is defined by the claims.

Furthermore, the following claims are hereby incorporated into the Description of Preferred Embodiments, where each claim may stand on its own as a separate embodiment. While each claim may stand on its own as a separate embodiment, it is to be noted that-although a dependent claim may refer in the claims to a specific combination with one or more other claims-other embodiments may also include a combination of the dependent claim with the subject matter of each other dependent or independent claim. Such combinations are proposed herein unless it is stated that a specific combination is not intended. Furthermore, it is intended to include also features of a claim to any other independent claim even if this claim is not directly made dependent to the independent claim.

It is further to be noted that methods disclosed in the specification or in the claims may be implemented by a device having means for performing each of the respective acts of these methods.

### REFERENCE LIST

1 Substrate
2.1-2.6 Slots
3 Main body (of the substrate)
4 Micro-positioning system
5 Beam path
6.1-6.6 Components (of optical laser cavity)
7 Yaw micro-positioner
8 Pitch micro-positioner
9.1-9.4 Flexure arms
10 Carrier platform
11 Yaw actuation flexure beam
12 First yaw area (of yaw actuation flexure beam)
13 Second yaw area (of yaw actuation flexure beam)
14 First end (of yaw actuation flexure beam)
15 Second end (of yaw actuation flexure beam)
16 Laser pattern (yaw)
17 Pulling force
18 Flexible element (of yaw actuation flexure beam)
19 Rigid element (of yaw actuation flexure beam)
20 Yaw axis
21 Anticlockwise rotation (around yaw axis)
22 Neutral area (of yaw actuation flexure beam)
23 Pitch actuation flexure beam
24 First pitch area
25 Second pitch area
26 Yaw-sub-platform
27 Pitch-sub-platform
28 Flexible transmission beam
29 Rigid transmission beam
30 Cross pivot
31 Laser pattern (pitch)
32 Pitch axis
33 Clockwise rotation (around pitch axis)
34 Neutral area (of pitch actuation flexure beam)
A-A′ Cut from A to A′ through the substrate
S1 Placement step
S2 Micro-positioning step

1. A substrate for holding a multitude of components of an optical laser cavity,
wherein the substrate comprises a multitude of slots,
wherein each slot is configured to receive one of the components,
wherein the substrate comprises a micro-positioning system configured to enable a micro-positioning of at least one of the components after this component has been received in its corresponding slot.

2. The substrate according to claim 1, wherein the micro-positioning system is configured to be actuated by at least one of: a laser, an electrostatic force, or a mechanical force.

3. The substrate according to claim 1, wherein the micro-positioning system comprises at least one micro-positioner that comprises one or more deformable elements.

4. The substrate according to claim 1, wherein the micro-positioning system is configured to permanently change its shape when being actuated by means of a laser.

5. The substrate according to claim 1, wherein the micro-positioning system is configured to at least one of temporarily or dynamically change its shape when being actuated by at least one of: an electrostatic force, a mechanical force, or by a force caused by at least one of a thermal expansion or shrinkage of an element.

6. The substrate according to claim 4, wherein the micro-positioning system is configured such that the permanent shape modification comprises a shrinkage or expansion of material volume.

7. The substrate according to claim 3, wherein at least one of the micro-positioners or a deformable element of the micro-positioner has one or two or three or more degree(s) of freedom, wherein the at least one of the micro-positioners or the deformable elements is configured such that its degrees of freedom can be individually adjusted.

8. The substrate according to claim 1, wherein the micro-positioning system comprises at least one of a yaw-micro-positioner or a pitch-micro-positioner.

9. The substrate according to claim 8, wherein
the yaw-micro-positioner comprises a carrier platform, wherein the carrier platform comprises a platform slot for receiving a component on which the micro-positioning is to be performed,
wherein the yaw-micro-positioner comprises a multitude of flexure arms, wherein the flexure arms connect the carrier platform to a main body of the substrate,
wherein the yaw-micro-positioner comprises a yaw actuation flexure beam, wherein the yaw actuation flexure beam comprises a first yaw area and a second yaw area, wherein the yaw actuation flexure beam comprises a first end and a second end,
wherein the first end of the yaw actuation flexure beam is attached to the main body of the substrate and wherein the second end of the yaw actuation flexure beam is attached to the carrier platform.

10. The substrate according to claim 8, wherein
the pitch-micro-positioner comprises a pitch actuation flexure beam, wherein the pitch actuation flexure beam comprises a first pitch area and a second pitch area, and wherein at least one of:
the pitch actuation flexure beam is configured to at least one of shrink or expand when a laser pattern is written onto at least one of the first pitch area or onto the second pitch area, or
the pitch actuation flexure beam has an essentially rectangular form.

11. The substrate according to claim 10, wherein at least one of:
the carrier platform comprises the pitch-micro-positioner,
the carrier platform comprises a yaw-sub-platform and a pitch-sub-platform, wherein the yaw-sub-platform comprises the platform slot and wherein the pitch-sub-platform comprises at least one of the pitch-micro-positioner or the pitch actuation flexure beam,
the carrier platform comprises a flexible transmission beam,
the carrier platform comprises a rigid connection beam,
the flexible transmission beam is directly connected to the pitch-sub-platform and to the rigid connection beam, or
the rigid connection beam is directly connected to the flexible transmission beam and to the yaw-sub-platform.

12. The substrate according to claim 3, wherein at least one of a multitude of micro-positioners or deformable elements are distributed across at least one of the substrate or along a beam path of the optical laser cavity such that the micro-positioning system configured to enable a micro-positioning of a multitude of the components of the laser cavity once these components have been placed in their corresponding slots.

13. A method for manufacturing the substrate according to claim 1, wherein the method comprises at least one of a step of femtosecond laser-machining, a step of chemical etching, a step of reactive-ion etching (RIE); or of deep reactive-ion etching (DRIE).

14. A method for optimizing a position of a component of an optical laser cavity on a substrate, wherein the method comprises:
a placement step, during which the component is placed in a slot of the substrate configured to receive the component,
a micro-positioning step, during which a position of the component received in the slot is optimized by actuating a micro-positioning system of the substrate.

15. The method according to claim 14, wherein during the micro-positioning step, the substrate is being exposed to a laser so as to generate a shrinkage or expansion of material volume.

16. The substrate according to claim 4, wherein at least one of the micro-positioner or a deformable element of the micro-positioner is configured to undergo a permanent shape modification when being actuated by means of the laser.

17. The substrate according to claim 5, wherein at least one of the micro-positioner or a deformable element of the micro-positioner is configured to undergo at least one of a temporary or dynamic shape modification when being actuated by at least one of: the electrostatic force, the mechanical force, or the force caused by at least one of thermal expansion or shrinkage of the element.

18. The substrate according to claim 6, wherein the micro-positioning system is configured such that the permanent shape modification comprises a shrinkage or expansion of substrate material volume.

19. The substrate according to claim 9, wherein at least one of:
the carrier platform has an essentially rectangular surface,
the yaw actuation flexure beam is configured to at least one of shrink or to expand when a laser pattern is written onto at least one of the first yaw area or onto the second yaw area,
the second end of the yaw actuation flexure beam is attached to an edge of the carrier platform, or
each flexure arm is attached to a corner of the carrier platform.

20. The method according to claim 15, wherein during the micro-positioning step, at least one of a micro-positioner or a deformable element of the micro-positioning system is being exposed to a laser so as to generate a localized shrinkage or expansion of substrate material volume.
